(19) United States
(12) Patent Application Publication
(10) Pub. No.: US 2002/0175341 A1
(43) Pub. Date: Nov. 28, 2002

(54) Process for production of a nitride semiconductor device and a nitride semiconductor device

(76) Inventors: Goshi Biwa, Kanagawa (JP); Hiroyuki Okuyama, Kanagawa (JP); Masato Doi, Kanagawa (JP); Toyoharu Oohata, Kanagawa (JP)

Correspondence Address: Bell, Boyd & Lloyd LLC, P.O. Box 1135, Chicago, IL, 60690, US

(21) Appl. No.: 10/127,153

(22) Filed: Apr. 18, 2002

(30) Foreign Application Priority Data
Apr. 19, 2001 (JP) P2001-121689

(51) Int. Cl. H01L 21/00; H01L 21/31; H01L 21/469; H01L 33/00

(52) U.S. Cl. 257/103; 438/46; 438/763; 438/767; 257/94

(57) ABSTRACT

Nitride semiconductor devices and methods of producing same are provided. The present invention includes forming an active layer on a substrate by vapor phase growth at a first temperature and forming thereon one or more nitride semiconductor layers at a temperature which is greater from the first temperature, such as by about 250° C. or less. The nitride semiconductor devices of the present invention can be used in a variety of different applications.

### RELATED APPLICATION DATA

The present invention claims priority to Japanese Patent Document No. P2001-121689 filed on Apr. 19, 2001 herein incorporated by reference to the extent permitted by law.

### BACKGROUND OF THE INVENTION

The present invention generally relates to a process for production of a nitride semiconductor device. More specifically, the present invention relates to growing on a substrate a nitride semiconductor, such as gallium nitride compound semiconductor that can be used in a variety of suitable applications, such as a light-emitting device including, for example, a semiconductor diode, a semiconductor laser or the like.

Known semiconductors include nitride compound semiconductors (such as GaN, AlGaN, and GaInN) composed of elements belonging to Groups III and V and have a broad bandgap width ranging from 1.8 eV to 6.2 eV. In theory, this makes it possible to achieve light-emitting devices capable of emitting light spanning a broad spectra covering red to ultraviolet.

Light-emitting diodes (LED) and semiconductor lasers of group III-V nitride compound semiconductor typically have a laminate structure with multiple layers of GaN, AlGaN, GaInN, or the like such that the light-emitting layer (or active layer) is held between an n-type cladding layer and a p-type cladding layer. Some known semiconductor devices have the light-emitting layer in quantum well structure of GaInN/GaN or GaInN/AlGaN.

The quantum well structure of GaInN/GaN or GaInN/AlGaN with good crystal properties should be formed in such a way that the GaN layer or AlGaN layer (as the barrier layer) is grown at a high temperature of about 1000° C. and the GaInN layer (as the well layer) is grown at a low temperature of 700° C. to 800° C.

However, growing the GaInN layer (as the well layer) at a low temperature of 700° C. to 800° C. and then growing the GaN layer or AlGaN layer (as the barrier layer) at a high temperature of about 1000° C. can be problematic. In this regard, the underlying GaInN layer can deteriorate, and thus decrease the light-emitting power of the semiconductor device. One reason for this is that gallium nitride compound semiconductors usually vary in growth temperature depending on the composition of compound crystal. The growth temperature of InGaN with an ordinary composition of 10-20% is 700° C. to 800° C., whereas that of GaN is higher than 1000° C. It follows therefore that the InGaN layer grown first experiences a higher temperature than its growth temperature when the GaN layer is grown thereon later. This results in an active layer with poor crystal properties due to breakage of In-N bonds in the InGaN layer which gives nse to nitrogen voids and the formation of metallic indium. In addition, if layers with a pn junction are formed at a low temperature and subsequently exposed to a high temperature, the semiconductor can deteriorate in characteristic properties on account of the diffusion of n-type or p-type impurity atoms. Such deterioration, in general, can occur not only in the GaInN layer but also in the layer of In-containing group III-V nitride compound semiconductor.

This occurs with semiconductor light-emitting devices (such as LED and laser diodes (LD)) in which an n-type GaN layer, an InGaN active layer, and a p-type GaN layer are formed sequentially one over the other. Growth of the p-type GaN (or AlGaN layer) on the InGaN active layer deteriorates the latter. Marked deterioration in performance occurs particularly in those devices emitting visible light whose active layer and p-type GaN layer are grown at greatly different temperatures.

One known way to solve the problem arising from the growth temperature of the layer on the active layer is to form a GaN cap layer (about 10-40 nanometers (nm) in thickness) at a low temperature, as disclosed in Japanese Patent Laid-open No. Hei 10-32349. However, this is not a complete solution because the InGaN active layer is still subject to deterioration so long as another layer is formed at a high temperature on the GaN cap layer which has been formed at a low temperature.

Moreover, there is another disadvantage in growing a layer on the active layer at a low temperature for its protection. That is, gallium nitride compound semiconductors are liable to pitting when grown at a temperature lower than an optimal growth temperature. This holds true with the semiconductor light-emitting device composed of an n-type GaN layer, an InGaN active layer, and a p-type GaN layer, which are sequentially formed on top of the other, with the last being grown at about 950° C. As a result, pitting can increase current leakage. Alternatively, growth at 1000° C. or above gives a p-type GaN layer in the form of flat film free of pitting, but it deteriorates the active layer for the reason mentioned above.

A need, therefore, exists to provide improved nitride semiconductors that can be readily made and effectively applied in a variety of suitable applications.

### SUMMARY OF THE INVENTION

The present invention relates to a process for production of a nitride semiconductor device which includes the steps of forming an active layer on a substrate by vapor phase growth at a first growth temperature, and subsequently forming thereon one or more nitride semiconductor layers at a temperature effective to form the additional layer(s) on the active layer without causing, or at least greatly reducing, deterioration of the active layer. In an embodiment, the temperature is maintained at a temperature greater than the first growth temperature by about 250° C. or less, preferably about 150° C. or less. This can prevent breakage of In—N bonds in the active layer which can cause nitrogen voids and the formation of metallic indium. This allows the active layer to retain desirable crystal properties.

In this regard, the present invention can overcome, for example, the above-mentioned technical problem which arises when an active layer and a nitride semiconductor layer thereon are grown at different temperatures. As a result, the present invention can provide an improved nitride semiconductor device with enhanced characteristics and properties, such as light-emitting characteristics and other suitable properties.

In an embodiment, the present invention includes a process for production of nitride semiconductor device which includes the steps of forming an active layer on a substrate by vapor phase growth at a first temperature, and subsequently forming thereon one or more nitride semiconductor layers at a second temperature which is greater than the first temperature by about (1350-0.75λ)° C. or less, preferably about (1250-0.75λ)° C. or less, where λ denotes the wavelength (nm) of light emitted by the active layer. Applicants have demonstrated that the process of the present invention conducted at such specific temperatures can effectively protect the active layer from deterioration.

In an embodiment, the present invention includes a process for production of a nitride semiconductor device which includes the steps of forming an active layer of an In-containing compound crystal on a substrate by vapor phase growth at a first temperature, and subsequently forming thereon one or more nitride semiconductor layers at a second temperature (T) which is greater than the first temperature by (1080-4.27X)° C. or less, preferably about (980-4.27X)° C. or less, where X denotes the In content (%) in the active layer.

Applicants have demonstrated that the upper limit of the growth temperature can depend on the wavelength of emitted light as mentioned above and, in addition, the growth temperature of all the nitride semiconductor layers on the active layer can depend on the In content (%) in the compound crystal constituting the active layer. This dependence can be characterized by the linear relationship between temperature and In content, i.e., temperature (1080-4.27X)° C. as previously discussed, which was experimentally found. At such definable temperatures, the active layer can be protected from deterioration.

In an embodiment, the present invention includes a first nitride semiconductor layer, an active layer formed on said first nitride semiconductor layer, and a second nitride semiconductor layer formed on said active layer which has a conductivity type opposite to that of said first nitride semiconductor layer, wherein the second nitride semiconductor layer being one which is formed at a growth temperature no higher than about 900° C. and having a thickness in size effective to define a smooth surface.

In an embodiment, the nitride semiconductor device of the present invention can include the second nitride semiconductor layer formed on the active layer at a temperature no higher than about 900° C. As a result, a smooth surface can be obtained. In an embodiment, the second nitride semiconductor layer can have a thickness larger than about 50 nm, preferably larger than about 100 nm, which can facilitate the formation of a smooth surface.

In an embodiment, the nitride semiconductor layer is a gallium nitride layer. When grown at about 950° C., a gallium nitride layer is suspect to pitting. Applicants have demonstrated that when grown at a temperature no higher than about 900° C., a gallium nitride layer has a smooth surface substantially free of pitting. It is believed this is because the surface diffusion length of Group III atoms is short at such a low temperature. As a result, a semiconductor device fabricated according to an embodiment of the present invention has a low leakage current.

Additional features and advantages of the present invention are described in, and will be apparent from, the following Detailed Description of the Invention and the figures.

### BRIEF DESCRIPTION OF THE FIGURES

FIG. 1 is a graph showing the growth temperature of the nitride semiconductor layers which changes with time in the production of the nitride semiconductor device according to an embodiment of the present invention.

FIG. 2 is a sectional view showing the steps up to the formation of the p-type GaN layer in the production of the nitride semiconductor device according to an embodiment of the present invention.

FIG. 3 is a sectional view showing the steps up to the formation of the electrode layer in the production of the nitride semiconductor device according to an embodiment of the present invention.

FIG. 4 is a graph showing the relation between the mobility and the growth temperature of the nitride semiconductor layer in a GaN-based semiconductor device.

FIG. 5 is a graph showing the relation between the wavelength of light emitted by the active layer of the GaN-based semiconductor device and the growth temperature for the layers on the active layer according to an embodiment of the present invention.

FIG. 6 is a sectional view showing the steps up to the formation of the p-type GaN contact layer in the production of the nitride semiconductor device according to an embodiment of the present invention.

FIG. 7 is a sectional view showing the steps up to the formation of the electrode layer in the production of the nitride semiconductor device according to an embodiment of the present invention.

FIG. 8A is a sectional view showing the steps up to the formation of the p-type GaN layer in the production of the nitride semiconductor device according to an embodiment of the present invention.

FIG. 8B is a sectional view showing the steps up to the formation of the electrode layer in the production of the nitride semiconductor device according to an embodiment of the present invention.

FIG. 9 is a sectional view showing the nitride semiconductor device according to an embodiment of the present invention.

### DETAILED DESCRIPTION OF THE INVENTION

The present invention will be described in more detail with reference to the accompanying drawings. According to an embodiment of the present invention, the process for production of nitride semiconductor device includes forming an active layer on a substrate by vapor phase growth at a first growth temperature, and subsequently forming thereon one or more nitride semiconductor layers at a second growth temperature which is greater than the first growth temperature by about 250° C. or less.

In an embodiment, all of the layers on the active layer are grown at a temperature which should not exceed the growth temperature of the active layer by more than about 250° C. For example, in the case where the active layer is grown at about 650° C., all of the layers on the active layer should be grown at a temperature no higher than about 900° C. Applicants have discussed that growth at a temperature exceeding this limit can thermally deteriorate the active layer.

The active layer may be a compound crystal containing indium such as an InGaN layer or other suitable indium-based material. The In-containing compound crystal, such as InGaN, has a higher In content and a lower growth temperature in proportion to the wavelength of the light it emits. Since In—N bonds are less stable to heat than Ga—N bonds, all the layers on the active layer should be grown at a low temperature. Nitride semiconductor devices (including LED and LD) emit light with a wavelength ranging from about 370 nm to about 640 nm with an active layer formed from InGaN.

By way of example, and not limitation examples according to an embodiment of the present invention will be described below.

### EXAMPLE 1

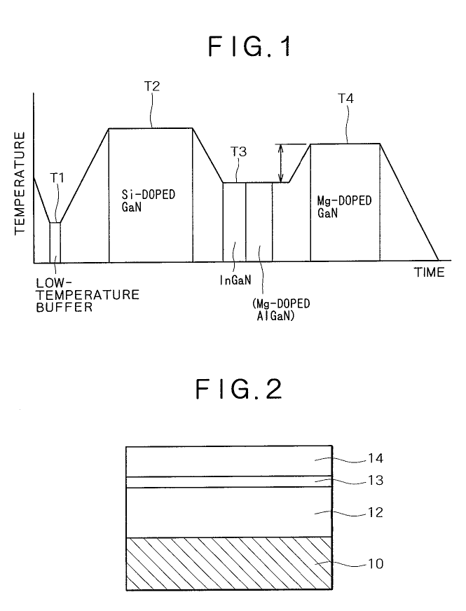

This example demonstrates the process for production of a nitride semiconductor device according to an embodiment of the present invention as shown in FIGS. 1 to 3.

FIG. 1 is a diagram showing the growth temperature which varies with time for different layers. It is noted that the initial growth temperature (T1) for the buffer layer is about 500° C. as shown in FIG. 1. The growth temperature is raised to T2 (about 1020° C.) for the silicon-doped n-type GaN layer. With the supply of trimethylgallium suspended temporarily, the growth temperature is lowered to T3 (about 730° C.). With the growth temperature kept at 730° C., an active layer of InGaN (30 angstroms (Å) thick) is grown from trimethylgallium (as a gallium source) and trimethylindium (as an indium source) after the carrier gas has been switched from a mixture to nitrogen.

After the active layer of InGaN has been formed, the magnesium-doped AlGaN layer is grown thereon at the growth temperature of T3. Subsequently, with the growth temperature raised to T4 (about 900° C.), the magnesium-doped p-type GaN layer is formed thereon.

It is apparent from the graphical representation of the changing growth temperature that the difference between T4 and T3 is less than about 250° C. such as about 170° C. (with T3 being the growth temperature for the InGaN active layer and T4 being the growth temperature for the magnesium-doped p-type GaN layer formed thereon). In other words, the magnesium-doped p-type GaN layer is not formed at 1020° C. which is conventionally regarded as the optimal temperature for GaN. In addition, the magnesium-doped p-type GaN layer is a layer which is formed at the highest temperature among those layers which are formed after the active layer has been formed. That is, other layers (on the active layer) are formed at a growth temperature lower than T4. In other words, all the layers on the active layer are formed at a growth temperature which does not exceed the growth temperature for the active layer by more than about 250° C. Growth at such temperatures can prevent the active layer from having breakage of In—N bonds therein which can give rise to nitrogen voids and metallic indium. This allows the active layer to retain good crystal properties and to emit light efficiently.

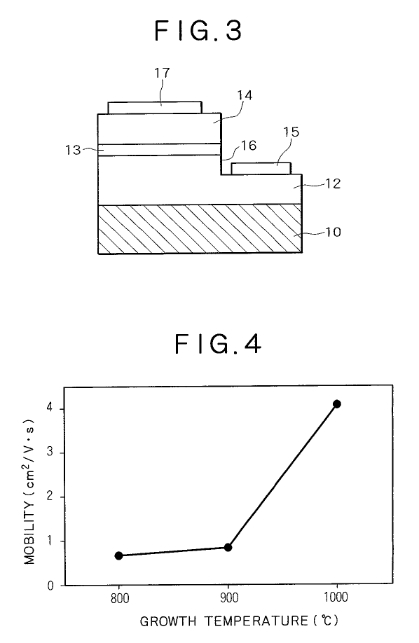

The process according to this example will be described in more detail with reference to FIGS. 2 and 3 which show the structure of the resulting device. The process starts with placing a sapphire substrate 10 (about 2 inches in diameter) in a reaction chamber (not shown) for vapor growth from organometallic compounds. The reaction chamber is continuously supplied with a carrier gas, which is a mixture of hydrogen (H₂) and nitrogen (N₂), for example. The sapphire substrate 10 is heated at 1050° C. for about 20 minutes under a stream of this carrier gas so that its surface is cleaned. With the substrate temperature lowered to about 510° C. (T1), the reaction chamber is supplied with ammonia (NH₃) as a nitrogen source and trimethylgallium (Ga(CH₃)₃) as a gallium source, so that a GaN buffer layer is grown on the sapphire substrate 10 whose principal plane is c-plane. On the GaN buffer layer is formed a silicon-doped n-type GaN layer 12 (3 microns thick) at 1020° C. (T2). Silicon is supplied in the form of silane.

With the supply of trimethylgallium suspended temporarily, the carrier gas is switched from a mixture to nitrogen while the temperature of the reaction chamber is being lowered to about 730° C. (T3). The reaction chamber is supplied with trimethylgallium as a gallium source and trimethylindium as an indium source, so that an InGaN active layer 13 (30 Å thick) is grown on the n-type GaN layer 12.

After the InGaN active layer 13 has been grown at 730° C. (T3), a magnesium-doped AlGaN layer can be optionally formed as shown in FIG. 1. Then, the reaction chamber is supplied with trimethylgallium as a gallium source and methylcyclopentadienyl magnesium as a magnesium source. With the reaction temperature raised to about 900° C. (T4), the Mg-doped p-type GaN layer 14 (200 nm thick) is formed. The growth temperature of about 900° C. (T4) for the Mg-doped p-type GaN layer 14 is lower than the temperature which exceeds the growth temperature 730° C. (T3) for the InGaN active layer 13 by about 250° C. Growth at such a temperature can prevent the occurrence of nitrogen voids and metallic indium, thereby permitting the active layer to maintain desirable crystal properties, thus contributing to improved light-emitting efficiency. In other words, this example differs from the conventional technology that grow the Mg-doped GaN layer at 1020° C. which is a known optimal growth temperature of GaN. In this regard, the light-emitting diode made pursuant to an embodiment of the present invention can, for example, prevent precipitation of metallic indium in the active layer due to growth at a high temperature. Growth at temperatures according to an embodiment of the present invention, such as Example 1, can eliminate such disadvantages of known growth processes, thus resulting in an improved light-emitting efficiency.

Growth of the Mg-doped p-type GaN layer 14 is followed by annealing at about 800° C. in nitrogen. As shown in FIG. 3, a trench 16 is formed by partial removal of p-type GaN layer 14, InGaN active layer 13, and n-type GaN layer 12. A Ti/Al electrode (for n-side) is formed on the n-type GaN layer which is exposed in the trench 16. A Ni/Pt/Au electrode (for p-side) is formed on the p-type GaN layer 14. In this way, there is completed the desired semiconductor light-emitting diode.

In this example, the layer on the active layer 13 is grown at a temperature which does not exceed the growth temperature for the active layer 13 by more than about 250° C. In an embodiment, the temperature difference is about 170° C. Because of growth at such a temperature, metallic indium does not precipitate in the active layer 13 thus facilitating improved light-emitting efficiency for the same injection current. A typical Mg-doped GaN decreases in mobility as the growth temperature decreases even though the carrier density remains essentially the same, as shown in FIG. 4. In other words, mobility is low for the growth temperature below about 900° C. This can cause an increase resistance and an increased operating voltage.

The present invention may be applied not only to the production of GaN-based semiconductor device (as explained above in this example) but also to the production of GaN-based field effect transistors (FET) and other suitable applications. In addition, the above-mentioned GaN layer may be replaced by an AlₓGa₁₋ₓ layer or the like.

### EXAMPLE 2

This example demonstrates the process for production of a GaN-based semiconductor light-emitting device according to an embodiment of the present invention that has a similar structure as that in Example 1. This example is based on the fact that the wavelength of the light emitted from the GaN semiconductor light-emitting device varies depending on the growth temperature of the nitride semiconductor layer formed on the active layer.

Applicants have discovered through experimentation that the wavelength of the light emitted from the GaN semiconductor light-emitting device varies depending on the growth temperature of the nitride semiconductor layer formed on the active layer. Applicants conducted experiments on several kinds of GaN-based light-emitting diodes, each having the same structure as in Example 1 (or including an n-type GaN layer, an InGaN layer, and a p-type GaN layer) but differing in the growth condition for the active layer. The resulting samples were tested for the wavelength of the emitted light. The results of the experiment were as follows. In the case where the InGaN active layer is so formed as to emit light having a wavelength of 470 nm and the p-type GaN layer is formed subsequently on it at 950° C. or less, then the resulting light-emitting diode retains a high light-emitting efficiency without precipitation of metallic indium in the active layer. By contrast, in the case where the p-type GaN layer is formed subsequently on it at 1020° C., the resulting light-emitting diode is poor in light-emitting efficiency (for the same amount of injected current) due to precipitation of metallic indium in the active layer. It is believed that precipitated metallic indium can cause reactive current without contribution to light emission. In the case of InGaN active layer for a wavelength of 470 nm, the growth temperature of about 1000° C. can lead to a decrease in light-emitting efficiency. In the case of an active layer for a wavelength of 525 nm, no loss in light-emitting efficiency occurs so long as the p-type GaN layer is grown under 950° C. In the case of an active layer for a wavelength of 400 nm, no considerable loss in light-emitting efficiency is observed even though the p-type GaN layer is at 1020° C.

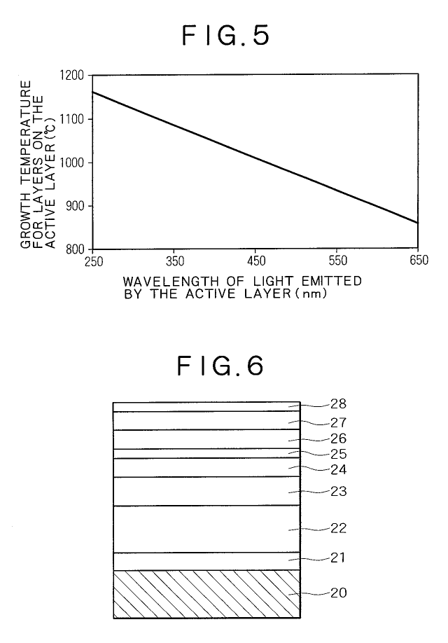

The results of the above-mentioned experiments are graphically shown in FIG. 5, with the ordinate representing the growth temperature (upper limit) for the p-type GaN layer formed on the active layer and the abscissa representing the wavelength of light emitted by the active layer. In this regard, FIG. 5 illustrates a linear relationship between the two variables, which is expressed by T=1350−0.75λ, where T is the growth temperature (° C.) and λ is the wavelength (nm). Pursuant to this relationship, the active layer can remain intact while nitride layers are being formed thereon.

The above-mentioned relationship between the growth temperature T (° C.) and the wavelength λ (nm) can be used to produce a light-emitting diode or the like. In other words, the growth temperature T (° C.) may be established according to the predetermined wavelength λ (nm). Thus, it is possible to produce a device in which the active layer remains intact and hence emits light efficiently.

### EXAMPLE 3

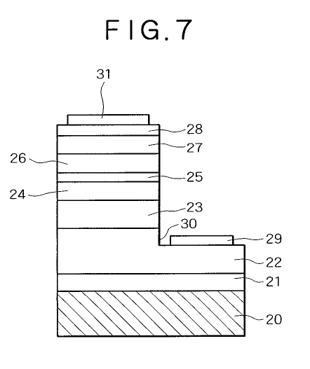

This example demonstrates a GaN-based semiconductor laser in which the active layer is a compound crystal of indium. The process for its production will be explained with reference to FIGS. 6 and 7.

First, a sapphire substrate 20 (whose principal plane is c-plane) undergoes thermal cleaning at about 1050° C. in the same way as in Example 1. On the substrate is grown a GaN or AlN buffer layer at about 510° C. With the reaction temperature raised to about 1020° C., an undoped GaN layer 21 (1 micron thick) and a silicon-doped n-type GaN layer 22 (3 microns thick) are grown sequentially. Silicon is introduced in the form of silane gas.

With the Si-doped n-type GaN layer 22 formed, the reaction chamber is supplied with NH₃ (as a nitrogen source), trimethylgallium (Ga(CH₃)₃ as a gallium source), and trimethylaluminum (Al(CH₃)₃, as an aluminum source), so that an n-type AlGaN cladding layer 23 is grown.

With the supply of NH₃ continued but the supply of trimethylgallium (“TMGa”) and trimethylaluminum (“TMAl”) suspended, the reaction chamber is cooled to about 700-850° C. (preferably about 720° C.). The supply of trimethylgallium (TMGa) is resumed, so that an n-type GaN guide layer 24 is formed. With this growth temperature (about 700° C. to about 850° C.) maintained, the reaction chamber is supplied with two reactant gases alternately. The first reactant gas is a combination of NH₃ (as a nitrogen source), trimethylgallium (TMGa) (as a gallium source), and trimethylindium (TMIn) (as an indium source). The second reactant gas is simply triethylgallium (TEGa) (as a gallium source). Thus, an active layer 25 of a multiple quantum well (MQW) structure is formed, in which three InGaN layers (30 Å thick each) and three GaN layers (50 Å thick each) are arranged alternately one over the other. The growing condition is established so that the In content in the active layer 25 is about 15%.

After the active layer 25 of multiple quantum well structure (MQW) has been formed, the reaction chamber is supplied with NH3 together with trimethylgallium (TMGa), with the growth temperature kept at about 700° C. to about 850° C. (preferably about 720° C.), so that a Mg-doped p-type GaN guide layer 26 is formed. The reaction chamber is supplied with NH₃ (as a nitrogen source), trimethylgallium (TMGa) (as a gallium source), and trimethylaluminum (TMAl) (as an aluminum source), so that a p-type AlGaN cladding layer 27 is grown. The reaction chamber is supplied with NH₃ and trimethylgallium (TMGa), (with the supply of trimethylaluminum (TMAl) suspended), so that a p-type GaN contact layer 28 is grown.

It should be noted that the growth temperature for the p-type GaN guide layer 26, p-type AlGaN cladding layer 27, and p-type GaN contact layer 28 is below about (1080-4.27X)° C. where X is the In content in wt %. Since the In content in the active layer is 15%, this growth temperature is about 1016° C. or less. In particular, the p-type GaN guide layer 26 and p-type AlGaN cladding layer 27 are grown at about 720° C., and the p-type GaN contact layer 28 is grown at about 900° C. These growth temperatures are lower than the upper limit which is about 1016° C. (i.e., 1080-4.27X). The growth temperatures are low enough for the active layer to retain its good crystal properties and protect itself from deterioration (such as occurrence of nitrogen voids and metallic indium due to breakage of In—N bonds). Therefore, this contributes to the light-emitting efficiency.

The upper limit of the growth temperature T (° C.) is empirically obtained from the equation of (1080-4.27X) as a function of the In content (X). The higher the In content, the lower the growth temperature.

The steps up to this stage complete the p-type nitride semiconductor layers, including the p-type GaN guide layer 26, p-type AlGaN cladding layer 27, and p-type GaN contact layer 28. After these steps, a trench 30 is formed so that the n-type GaN layer 22 (which is an n-type nitride semiconductor layer) is exposed, as shown in FIG. 7. On the exposed surface of the n-type GaN layer 22 is formed an Al/Ti electrode 29 (which is an n-side electrode). On the uppermost p-type GaN contact layer 28 is formed a Ni/Pt/Au electrode 31.

Thus, there is obtained the desired GaN-based semiconductor laser of multiple quantum well (MQW) structure which has a high light-emitting efficiency without the active layer being deteriorated, because the growth temperature for the p-type GaN guide layer 26, p-type AlGaN cladding layer 27, and p-type GaN contact layer 28 on the active layer 25 is lower than the upper limit defined by the above-mentioned equation in terms of the In content.

### EXAMPLE 4

This example demonstrates the process for production of a GaN-based semiconductor light-emitting device of almost the same layer structure as that in Example 1. This device is characterized in that the nitride semiconductor layers on the active layer are grown at about 900° C. or less and are thick enough for their surface to be flat planar or smooth in structure without pitting.

First, a sapphire substrate is placed in a reaction chamber (not shown) for organometallic vapor phase growth, as in Example 1. The reaction chamber is supplied with a mixture of H₂ and N₂ as a carrier gas. The sapphire surface undergoes thermal cleaning by heat treatment at about 1050° C. for about 20 minutes. With the substrate temperature lowered to, say, 510° C., the reaction chamber is supplied with ammonia (NH₃) (as a nitrogen source) and trimethylgallium (TMGa, Ga(CH3)₃) (as a gallium source), so that a GaN buffer layer is grown on the sapphire substrate. On the GaN buffer layer are grown at about 1020° C. an undoped GaN layer (1 micron thick) and a Si-doped n-type GaN layer (3 microns thick). Silicon is introduced in the form of silane gas.

With the supply of trimethylgallium suspended temporarily, the growth temperature is lowered to about 730° C. and the mixed carrier gas is switched to nitrogen. The reaction chamber is supplied with trimethylgallium (as a gallium source) and trimethylindium (as an indium source), so that an InGaN active layer (30 Å thick) is formed on the n-type GaN layer.

Then, the reaction chamber is supplied with trimethylgallium (as a gallium source) and methylcyclopentadienyl magnesium (as a magnesium source), so that a Mg-doped p-type GaN layer (200 nm thick) is grown at about 800° C. This growth temperature is sufficiently lower than the conventional one. At this growth temperature, it is believed that Ga atoms have so short a surface diffusion length allowing a uniform GaN layer having a flat surface to be deposited. The p-type GaN layer grown at such a low temperature differs from the one grown at 950° C. in that carriers in the same concentration (about 10¹⁵ cm⁻³) have a lower mobility (as shown in FIG. 4). This lower mobility slightly raises the operating voltage but permits uniform current injection and hence decreases current leakage. The result is an improved light-emitting efficiency for the same amount of injected current. Incidentally, the active layer emits light having a wavelength of 470 nm.

Devices for comparison were prepared by growing the p-type GaN layer at 950° C. (which is lower than the optimal growth temperature of GaN or 1000° C.) in place of 800° C. (which is a considerably low growth temperature). The active layer in the device showed no sign of indium precipitation but had its surface covered with pits defining inverted hexagonal pyramids each consisting of six stepped faces. Some pits were as deep as 200 nm (almost equal to the layer thickness). Devices with such pits encounter troubles such as current concentration, non-uniform current injection, and current leakage.

The foregoing suggests that the semiconductor light-emitting device has good characteristic properties if the nitride semiconductor layer therein is grown at about 800° C. and has a thickness large enough to prevent surface pitting to ensure a flat surface. In this regard, one or more layers can be formed on the active layer at a temperature low enough to prevent pitting, thus resulting in a semiconductor device protected from current leakage due to pitting. For example, the GaN layer grown at 1000° C. or above shows the smooth step flow with a few pits; however, the one grown at a temperature lower than that has many pits each taking on an inverted pyramid consisting of six stepped faces. However, the GaN layer grown at a further reduced temperature has less pits because of decrease in the surface diffusion length of Group III atoms. The device grown at such a low temperature may have somewhat less desirable crystal properties (due to point defects or the like) and have an increased resistance; however, it effectively prevents leakage current due to its smooth surface.

### EXAMPLE 5

This example demonstrates a nitride semiconductor device in which at least one of the semiconductor layers on the active layer is grown at a low temperature and has a smooth surface.

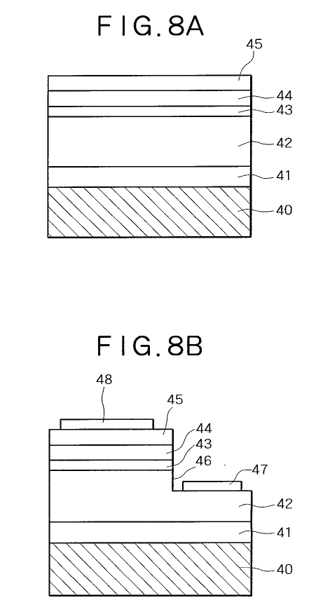

The device in this example is fabricated as shown in FIG. 8A. First, a sapphire substrate 40 is placed in a reaction chamber (not shown) for organometallic vapor phase growth, as in Example 1. The surface of the sapphire substrate 40 undergoes thermal cleaning by heat treatment at about 1050° C. for 20 minutes. With the substrate temperature lowered to, for example, about 510° C., the reaction chamber is supplied with ammonia (NH₃) (as a nitrogen source) and trimethylgallium (TMGa, Ga(CH3)₃) (as a gallium source), so that a GaN buffer layer is grown on the sapphire substrate.

On the GaN buffer layer are grown at about 1020° C. an undoped GaN layer 41 (1 micron thick) and a Si-doped n-type GaN layer 42 (3 microns thick). Silicon is introduced in the form of silane gas. With the supply of trimethylgallium suspended temporarily, the growth temperature is lowered to about 730° C. and the mixed carrier gas is switched to nitrogen. The reaction chamber is supplied with trimethylgallium (as a gallium source) and trimethylindium (as an indium source), so that an InGaN active layer 43 (30 Å thick) is formed on the n-type GaN layer 42.

After the InGaN active layer 43 has been formed, the reaction chamber is supplied with trimethylgallium (as a gallium source) and methylcyclopentadienyl magnesium (as a magnesium source), so that a Mg-doped p-type GaN layer 44 (100 mm thick) is grown at about 800° C. and then a Mg-doped p-type GaN layer 45 is grown at about 950° C.

At a growth temperature of about 800° C. (as in Example 4), gallium atoms with a short surface diffusion length deposit uniformly to form a GaN layer with a smooth surface. The p-type GaN layer 44 has a carrier concentration of about 1018 cm⁻³ which ensures uniform current injection with reduced leakage current. The p-type GaN layer 45, which is formed on the p-type GaN layer 44 at a growth temperature of about 950° C., has some pits; however, these pits are no deeper than the thickness (about 100 Å) of the GaN layer 45 which has been grown at 950° C. Therefore, the resulting device does not decrease in light-emitting efficiency unlike the one (in Example 4) in which all the layers are grown at about 800° C. The GaN layer 45 grown at a high temperature has a low contact resistance with the electrode, and the resulting device has a lower operating voltage than that in which all the p-type GaN layers are grown at about 800° C.

After the Mg-doped p-type GaN layer 45 (100 nm thick) has been grown at about 950° C., a trench 46 is formed as shown in FIG. 8B so that the surface of the n-type GaN layer 42 is exposed. On the exposed surface is formed an Al/Ti electrode 47 (as an n-side electrode) and on the uppermost p-type GaN layer 45 is formed a Ni/Pt/Au electrode 48. Thus, there is completed the semiconductor light-emitting diode.

The nitride semiconductor device in this example is characterized in that the nitride layers on the active layer are composed of a first layer which is grown at a lower temperature and has a smooth surface and a second layer which is grown at a higher temperature. This structure prevents the occurrence of pitting and eliminates current concentration and leakage current, with reduced contact resistance of the electrode.

### EXAMPLE 6

This example demonstrates a field effect transistor in which the InGaN active layer functions as the channel layer.

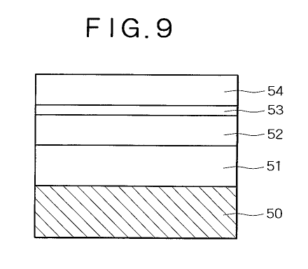

The field effect transistor, constructed as shown in FIG. 9, is fabricated in the following manner according to an embodiment of the present invention. First, a sapphire substrate 50 is placed in a reaction chamber (not shown) for organometallic vapor phase growth, as in Example 1. The surface of the sapphire substrate 50 undergoes thermal cleaning by heat treatment at about 1050° C. for 20 minutes. With the substrate temperature lowered to, about 510° C., the reaction chamber is supplied with ammonia (NH₃) (as a nitrogen source) and trimethylgallium (TMGa, Ga(CH3)₃) (as a gallium source), so that a GaN buffer layer is grown on the sapphire substrate.

On the GaN buffer layer are grown at 1020° C. an undoped GaN layer 51 (2 microns thick) and then an undoped AlGaN layer 52 (2 microns thick), with the reactant gas switched to the one which contains trimethylaluminum.

With the supply of trimethylgallium suspended temporarily, the growth temperature is lowered to about 800° C. and the mixed carrier gas is switched to nitrogen. The reaction chamber is supplied with trimethylgallium (as a gallium source) and trimethylindium (as an indium source), so that an InGaN channel layer 53 (30 Å thick) is formed on the undoped AlGaN layer 52. The In content is about 10%.

After the InGaN channel layer 53 has been formed, the reaction chamber is supplied with trimethylgallium (as a gallium source), trimethylaluminum (as an aluminum source), and silane (as a silicon source), so that a Si-doped AlGaN layer 54 is grown at about 1040° C. In this way the desired device is produced.

The resulting field effect transistor performs its amplifying function owing to the InGaN channel layer 53 in which the carrier movement is controlled by gate voltage applied through a gate electrode attached thereto, with an insulator interposed between them. It should be noted that the Si-doped AlGaN layer 54 (on the InGaN channel layer 53) is grown at about 1040° C. or below. This temperature is lower than the growth temperature of the channel layer 53 by less than about 250° C. (i.e., 1040° C.−800° C.=240° C.). Therefore, the InGaN channel layer 53 can be protected from precipitation of metallic indium. This can contribute to the improved device characteristics.

The nitride semiconductor device produced according to an embodiment of the present invention is characterized in that the layers on the active layer are grown at a specific temperature determined in response to the growth temperature of the active layer and the wavelength of light emitted by the active layer as previously discussed. Growth at such a specific temperature protects the active layer from deterioration. This is effective particularly for those devices which emit light with a wavelength shorter than 450 nm. The devices produced by the process of the present invention have an improved light-emitting efficiency because the active layer therein is exempt from precipitation of metallic indium.

In an embodiment, the nitride semiconductor device of the present invention may be modified such that an additional layer with a flat surface is formed on the active layer at a temperature lower than 900° C. This additional layer prevents pitting which cannot be avoided by simply reducing the growth temperature. The result is uniform current injection and reduced current leakage.

It should be understood that various changes and modifications to the presently preferred embodiments described herein will be apparent to those skilled in the art. Such changes and modifications can be made without departing from the spirit and scope of the present invention and without diminishing its attended advantages. It is therefore intended that such changes and modifications be covered by the appended claims.

The invention is claimed as follows:

1. A method of producing a nitride semiconductor device, the method comprising the steps of:
forming an active layer on a substrate by vapor phase growth at a first growth temperature; and
forming one or more nitride semiconductor layers on the active layer at a second growth temperature wherein the second growth temperature is greater than the first growth temperature by about 250° C. or less.

2. The method according to claim 1, wherein the nitride semiconductor layers are formed on the active layer at the second growth temperature which is greater than the first growth temperature by about 150° C. or less.

3. The method according to claim 1, wherein the active layer contains indium.

4. The method according to claim 3, wherein the active layer emits light having a wavelength ranging from about 640 nm to about 370 nm.

5. The method according to claim 1, wherein the nitride semiconductor layer comprises a gallium nitride layer.

6. A method of producing a nitride semiconductor device, the method comprising the steps of:
forming an active layer on a substrate by vapor phase growth; and
forming one or more layers of a nitride semiconductor material at a growth temperature equaling about (1350-0.75λ)° C. or less where λ represents a wavelength of light emitted by the active layer.

7. The method according to claim 6, wherein the growth temperature equals about (1250-0.75λ)° C. or less during the formation of all of the layers of the nitride semiconductor material on the active layer.

8. The method according to claim 6, wherein the growth temperature is about 1000° C. or less.

9. The method according to claim 6, wherein the active layer contains indium.

10. The method according to claim 9, wherein the active layer emits light having a wavelength ranging from about 370 nm to about 640 nm.

11. A method of producing a nitride semiconductor device, the method comprising the steps of:
forming an active layer composed of an indium-based compound crystal on a substrate by vapor phase growth; and
forming one or more layers of a nitride semiconductor material at a growth temperature equaling about (1080-4.27X)° C. or less where X represents an amount of the indium in the active layer.

12. The method according to claim 11, wherein the growth temperature equals about (980-4.27X)° C. or less during formation of all of the layers of the nitride semiconductor material on the active layer.

13. A nitride semiconductor device comprising:
a first nitride semiconductor layer;
an active layer formed on the first nitride semiconductor layer; and
a second nitride semiconductor layer formed on the active layer which has a conductivity type opposite to the first nitride semiconductor layer, wherein the second nitride semiconductor layer is formed at a growth temperature ranging from about 900° C. or less and having a definable thickness effective to form a surface without pitting.

14. The nitride semiconductor device according to claim 13, wherein the thickness of the second nitride semiconductor layer is about 50 nm or less.

15. The nitride semiconductor device according to claim 13, wherein the thickness of the second nitride semiconductor layer is about 100 mm or less.

16. The nitride semiconductor device according to claim 13, wherein the second nitride semiconductor layer is composed of a p-type.

17. The nitride semiconductor device according to claim 13, wherein the second nitride semiconductor layer is composed of a n-type.

18. The nitride semiconductor device according to claim 13, wherein the active layer is composed of a compound crystal containing indium.

19. The nitride semiconductor device according to claim 13, wherein the nitride semiconductor layer comprises a gallium nitride layer.
